(19) United States
(12) Patent Application Publication
(10) Pub. No.: US 2011/0120365 A1
(43) Pub. Date: May 26, 2011

(54) PROCESS FOR REMOVAL OF CONTAMINANTS FROM A MELT OF NON-FERROUS METALS AND APPARATUS FOR GROWING HIGH PURITY SILICON CRYSTALS

(76) Inventors: Hui She, Issaquah, WA (US); Geoffrey Crabtree, Vancouver, WA (US)

(21) Appl. No.: 12/626,180

(22) Filed: Nov. 25, 2009

(51) Int. Cl. C30B 11/00; C01B 33/037

(52) U.S. Cl. 117/74; 423/349; 117/206

(57) ABSTRACT

A process for removal of contaminants from a melt of non-ferrous metals comprising the following steps: providing an apparatus (1) for melting and solidifying non-ferrous metals comprising a crucible (2) for holding a non-ferrous metal melt and a process chamber (4), in which the crucible (2) can be placed, wherein the crucible (2) contains an additive (17), providing a melt (19) in the crucible (2), heating the melt (19) in the crucible (2) to a predetermined temperature, whereby the additive (17) can react with contaminants in the melt (19), and segregating the reacted contaminants from the melt (19).

### FIELD OF THE INVENTION

The invention relates to a process for removal of contaminants from a melt of non-ferrous metals and to an apparatus for growing high purity silicon crystals.

### BACKGROUND ART

For the production of solar cells high purity silicon is needed. The production of high purity silicon is difficult and expensive. It usually requires a multistage process to purify metallurgical silicon to the standard of purity needed for photovoltaic applications.

Sakaguchi and Maeda describe a process for removing silicon carbide from a silicon melt by filtration and oxidation (see “Koichi Sakaguchi and Masafumi Maeda: Decarburization of Silicon Melt for Solar Cells by Filtration and Oxidation”, in “METALLURGICAL TRANSACTIONS B”, Vol. 23 B, August 1992, 423-427). However, there are no filters that can work at such high temperature without introducing impurities into the melt. In addition, the described process does not remove dissolvable impurities. Finally, the system is very complicated and not applicable for industrial scale production. U.S. Pat. No. 4,877,596 discloses a method for the production of low carbon silicon by establishing a temperature gradient in a contaminated silicon melt and using seed crystals to assist the growth of a silicon carbide, which is thereby removed from the melt. Theoretically, the carbon content of the silicon melt can be reduced to the limit of carbon solubility in the melt by this method. However, silicon carbide will precipitate when the melt solidifies due to the solubility of carbon is much smaller in the solid than that in the liquid phase at the same temperature.

### SUMMARY OF THE INVENTION

The invention is therefore based on the object of improving a process for removal of contaminants from a melt of non-ferrous metals.

According to the invention, said object is achieved by a process for removal of contaminants from a melt of non-ferrous metals comprising the following steps: Providing an apparatus for melting and solidifying non-ferrous metals comprising a crucible for holding a non-ferrous metal melt and a process chamber, in which the crucible can be placed, wherein the crucible contains an additive, providing a melt in the crucible, heating the melt in the crucible to a predetermined temperature, whereby the additive can react with contaminants in the melt, and segregating the reacted contaminants from the melt.

The core of the invention consists in providing an additive in the crucible, which can react with the contaminants in the melt, such that the reacted contaminants can easily be segregated from the melt. The segregated contaminants can easily be removed from the melt. Particularly suitable for this purpose is silica sand (SiO₂) in micron size, provided on the bottom of the crucible. The sand particles can react with silicon carbide particles on the bottom of the crucible and can also get into the silicon melt by thermal convection, thereby gathering non-dissolvable contaminants such as silicon carbide and silicon nitride in the melt. They can furthermore react with silicon carbide particles to produce carbon mono oxide (CO) and silicon mono oxide (SiO).

The invention is also based on the object of improving an apparatus for growing high purity silicon crystals.

According to the invention, said object is achieved by an apparatus comprising a crucible for melting and solidifying silicon, a process chamber, into which the crucible can be placed, a temperature controller for controlling the temperature inside the process chamber, wherein the crucible contains an additive of high purity silica powder.

Such an apparatus allows growing of high purity silicon crystals in an easy and efficient way. It allows the large scale production of high purity silicon crystals. In particular, the whole purification and crystallization process can be carried out in a single system.

Features and details of the invention result from the description of an embodiment based on the drawings.

### BRIEF DESCRIPTION OF THE DRAWINGS

FIGS. 1-4 show an apparatus for growing high purity silicon crystals according to a first embodiment during different stages of the process.

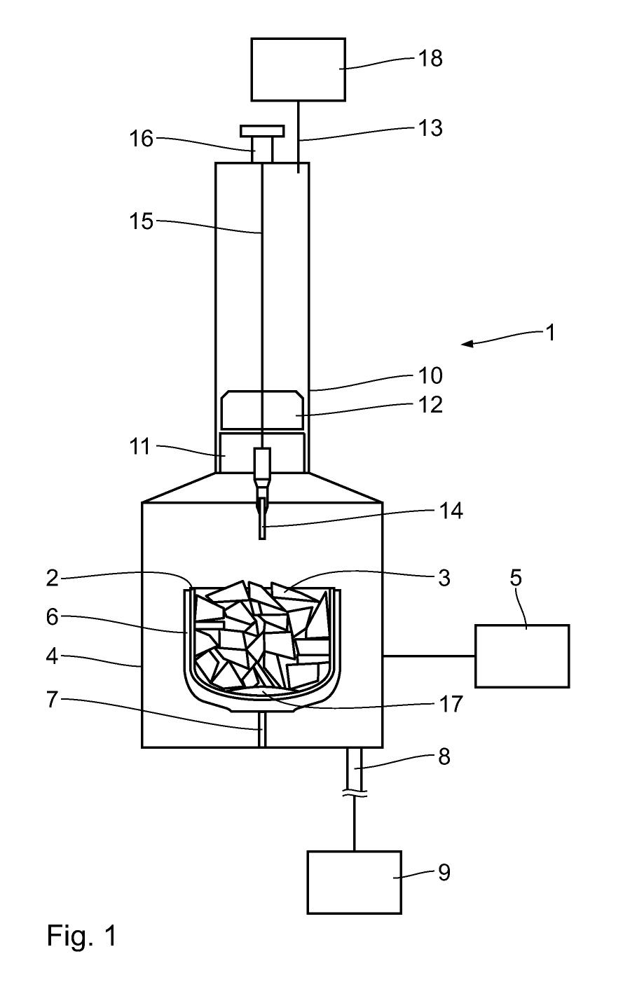

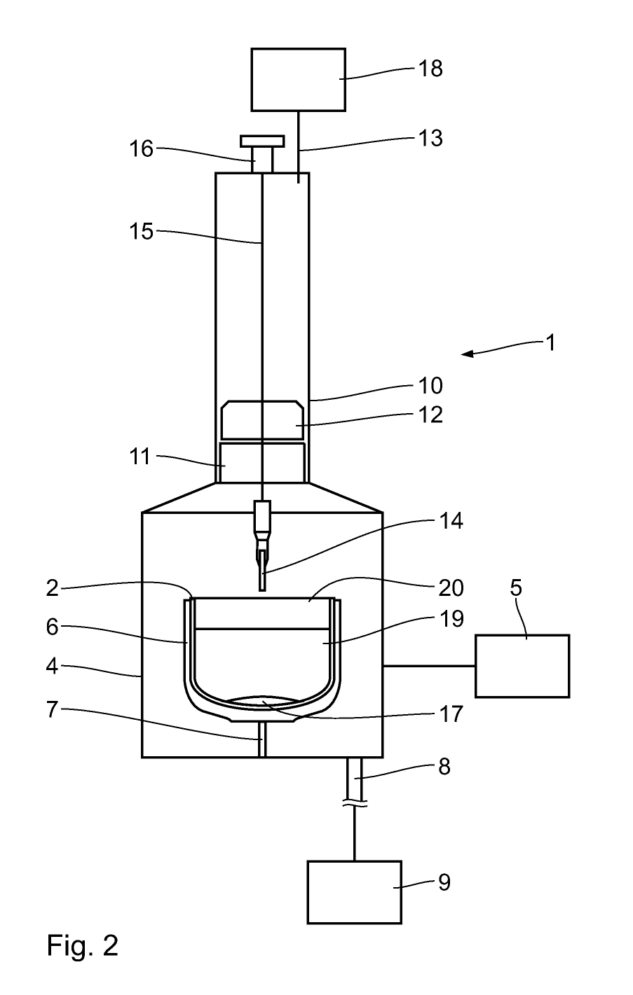

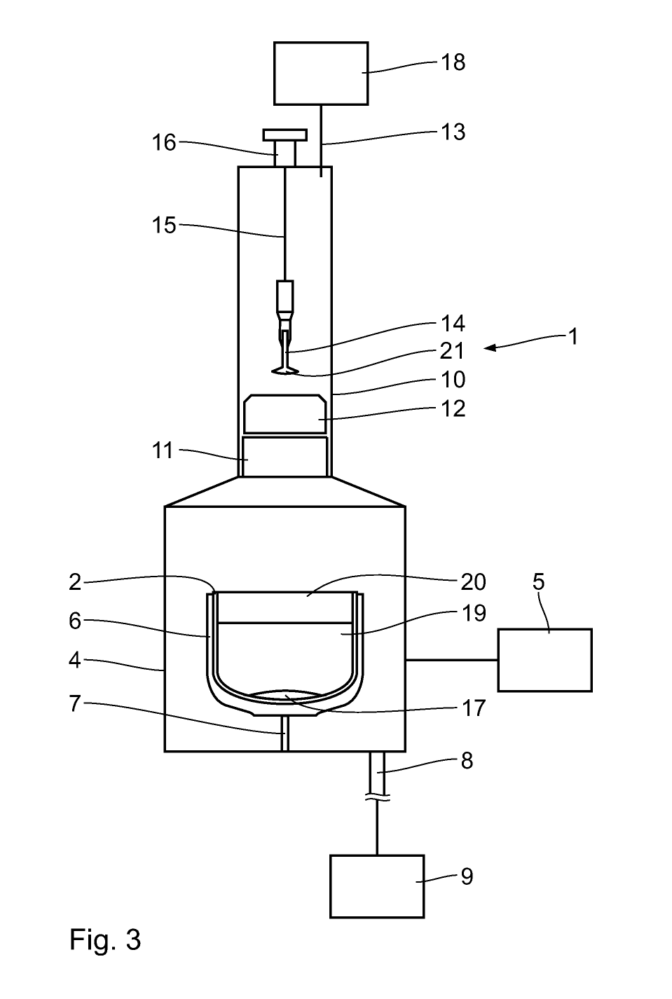

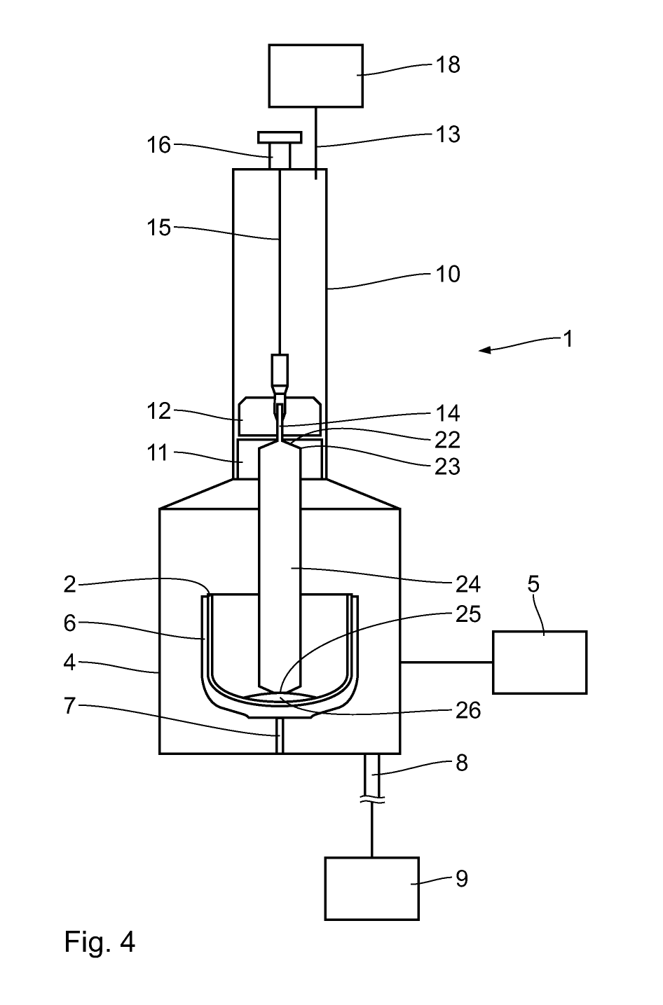

### DESCRIPTION OF THE PREFERRED EMBODIMENT

An apparatus 1 for growing high purity silicon crystals comprises a crucible 2 for melting and solidifying silicon 3, a process chamber 4, into which the crucible 2 can be placed, and a temperature controller 5 for controlling the temperature inside the process chamber 4.

The crucible 2 can also be used for melting and solidifying non-ferrous metals other than the silicon 3, in particular semiconductor material.

According to the first embodiment, the crucible 2 is a fused quartz crucible. The crucible can also be made of at least one of a ceramic, silicon carbide or silicon nitride. It can in particular have an inner layer comprising at least one of silicon nitride, silicon carbide or binder material and solvent on its inside to mitigate thermal stress during solidification and cool down. The inner layer is preferably a mixture of silicon nitride, silicon carbide, binder material and solvent.

In an alternative advantageous embodiment, the inner layer comprises silica (SiO₂). It can also consist of silica.

The crucible 2 has a round cross section. The cross section of the crucible 2 is preferably circular. However, alternative cross sections such as rectangular, in particular rectangular or quadratic cross sections are also possible. The crucible 2 is placed inside a graphite susceptor 6. The graphite serves as a mechanical support. The graphite susceptor 6 is placed on a pedestal 7.

The process chamber 4 is part of a furnace. It can be evacuated via a vacuum port 8 leading to a vacuum system 9. The vacuum system 9 can in particular remove gas from the process chamber 4. The process chamber 4 is connected to a pull chamber 10. The pull chamber 10 can be sealed from the process-chamber 4 by at least one of an isolation valve 11 or an isolation door 12, preferably by both, the isolation valve 11 and the isolation door 12.

A process gas inlet 13 is provided in the pull chamber 10. Via the process gas inlet 13, the pull chamber 10 is connected to a process gas system 18. The process gas system 18 comprises a process gas reservoir and a controllable process gas pump. Via the process gas system 18, the atmosphere inside the pull chamber 10 and the process chamber 4 is controllable. Advantageously, the gas removed from the process chamber 4 can be replaced by a process gas. The process gas is chosen from the inert gasses. In particular, argon is used as the process gas.

Both, the process chamber 4 and the pull chamber 10, can be completely sealed to the outside.

Inside the pull chamber 10, a seed crystal 14 can be lowered by a seed cable 15. The seed cable 15 is held by a rotation and lift device 16. When the isolation door 12 and the isolation valve 11 are open, the seed crystal 14 can be lowered into the process chamber 4, in particular into the crucible 2.

In a preferred embodiment, the apparatus 1 is built as a Czochralski silicon crystal puller.

According to the invention, the crucible 2 contains an additive 17. In an especially advantageous embodiment, silica sand (SiO₂) is used as the additive 17. Thus, the inner layer of the crucible 2 and the additive 17 can be made of the same material. The additive 17 consists in particular of synthetic silica sand. In a first example, the synthetic silica sand used as the additive 17 had less than 1 ppm wt impurities. The results of an analysis of the impurities in the synthetic silica sand used in the first example are shown in table 1.

TABLE 1
Impurities in the synthetic silica sand used

| Element | impurity (ppm-wt) |
|---|---|
| Al | ≦0.03 |
| Ca | ≦0.05 |
| Cr | ≦0.05 |
| Cu | ≦0.03 |
| Fe | ≦0.06 |
| K | ≦0.03 |
| Li | ≦0.03 |
| Na | ≦0.05 |
| Ni | ≦0.05 |
| Ti | ≦0.10 |
| Mg | ≦0.10 |
| Mn | ≦0.10 |
| B | ≦0.20 |

The silica sand had a particle size distribution with a maximum in the range between 50 μm and 500 μm, in particular in between 100 μm and 300 μm. The particle size distribution of the silica sand in the first example is shown in table 2.

TABLE 2
particle size distribution of the silica sand used

| | Particle size Microns | | | | | | | |
|---|---|---|---|---|---|---|---|---|
| | >425 | 300-425 | 212-300 | 150-212 | 106-150 | 75-106 | 45-75 | 0-45 |
| Sample (%) | 0.1 | 16 | 27.2 | 24.5 | 18.2 | 11.3 | 2.4 | 0.3 |

In the following, a process for a removal of contaminants from a melt of non-ferrous metals according to the invention is described. To start with the apparatus 1 as described above is provided. Herein the silica sand used as the additive 17 is provided on the bottom of the crucible 2. A predetermined amount of the additive 17 is provided, depending on the size of the crucible, the amount of the silicon 3 to be placed inside the crucible 2, or the amount of the impurities, in particular carbon impurities. It was found that addition of 20 g additive 17 was sufficient for the removal of the contaminants from a charge of 50 kg silicon 3. More generally the amount of additive 17 lies in the range of 0.00001 to 0.01 of the amount of silicon 3, in particular in the range of 0.0001 to 0.001 of the amount of silicon 3. The silicon 3 is placed inside the crucible 2 in form of chips and chunks. Alternatively, it is possible to melt the silicon 3 first and put it inside the crucible 2 in liquid form.

After the silicon 3 is charged into the crucible 2, the crucible 2 is loaded into the process chamber 4. Then, the process chamber 4 is pumped to a certain vacuum level by the vacuum system 9 via the vacuum port 8. Preferably, the vacuum inside the process chamber 4 is in the range of 10⁻⁶ mbar to 10⁻³ mbar. Then, the process gas, in particular argon, is introduced into the pull chamber 10 and the process chamber 4 via the process gas inlet 13 of the process gas system 18. After that, the temperature inside the process chamber 4 is raised to at least the melting point of silicon, 1420° C. Preferably the temperature is raised to a level in the range of 1500° C. to 1700° C.

After the silicon 3 is molten, it is inside the crucible 2 in form of a silicon melt 19 having a surface 20. The melt 19 can contain impurities of silicon carbide and silicon nitride as well as other contaminants. The impurities can be in the melt 19 in dissolved or in non-dissolved form. Whereas some of the non-dissolved impurities sink to the bottom of the crucible 2, others move in the melt 19 with a thermal convection current or stay on the surface 20 of the melt 19. In particular, silicon carbide and silicon nitride tend to sink to the bottom of the crucible 2 since their densities of 3.2 g/cm³ and 3.4 g/cm³, respectively are higher than the density of liquid silicon, 2.57 g/cm³. The impurities which sink to the bottom of the crucible 2 get in contact with the additive 17 there. They become bonded to the residue of the softened silica sand, thus forming larger lumps which stay on the bottom of the crucible 2 for the remaining purification process. Thus, the additive 17 acts as a binder fusing non-dissolvable contaminants to form larger lumps. In other words the additive 17 physically reacts with the contaminants to form aggregates.

The density of silica sand, 2.65 g/cm³, is only slightly higher than that of liquid silicon, 2.57 g/cm³. Thus, some of the silica sand provided at the bottom of the crucible 2 gets into the silicon melt 19 by thermal convection. There it gathers contaminating particles, which then sink to the bottom of the crucible 2 and stay there for the remaining purification process.

In the melt 19 some of the silica sand chemically reacts with impurities containing carbon to form a gas. In particular, carbon and silicon carbide will react with the silica sand to form carbon mono oxide (CO) at high temperatures. The carbon mono oxide will leave the silicon melt 19. The reaction continues until the equilibrium pressure for carbon mono oxide is reached at the surface 20 of the silicon melt 19. To enhance the reaction of the silica sand with carbon or silicon carbide in the melt, the carbon mono oxide gas above the surface 20 of the melt 19 is continuously removed from the process chamber 4 by at least one of the vacuum system 9 or the process gas system 18. For this purpose, a continuous flow of process gas is maintained in the process chamber 4, in particular along the surface 20 of the melt 19. In the example, argon was used as process gas.

Theoretically, carbon and silicon carbide can be completely removed from the silicon melt 19 as long as the quantity of silica sand is large enough and the product of the reaction, namely the carbon mono oxide gas, is removed. To remove contaminants containing carbon or silicon carbide from the melt 19, the melt 19 is kept at a temperature in the range between 1500° C. and 1700° C., in particular in the range between 1500° C. and 1600° C. for a period of at least one hour, preferably for a period in the range of between three hours and five hours. The process temperature determines the reaction speed, wherein a higher temperature leads to a faster reaction. However, the maximum temperature is limited by the heat-resistance of the crucible 2. The longer the melt 19 is held at this process temperature, the more complete is the removal of the contaminants.

Excess silica sand particles in the melt 19 eventually disappear from the melt 19 by reacting with the silicon in the melt 19 to become silicon mono oxide gas which is also removed from the process chamber 4 by the process gas flow.

The micron size of synthetic silica powder provides a large surface area to contact carbon and silicon carbide in the melt 19 for chemical reaction. In case of a coating of the crucible 2 containing silica or consisting of silica, this coating will also participate in the process of removing contaminants from the melt 19. However, due to the large specific surface area of the silica sand used as the additive 17, the efficiency of the reaction between the additive 17 and the contaminants is much higher.

Some of the contaminants will float on the surface 20 of the melt 19 due to surface tension. In order to remove the contaminants floating on the surface 20 of the melt 19, the seed crystal 14 being attached to the seed cable 15 is lowered to contact the melt 19 and to grow a plug to remove the floating contaminants. As seed crystal 14, a silicon seed is advantageously used. To assist the removal of the floating contaminants, the temperature field in the process chamber 4 and the position of the crucible 2 inside the process chamber 4 is controlled such that the temperature at the bottom and at the outside of the crucible 2 is higher than that at its surface and at its centre. By this setting, the thermal convection will always force the solid contaminants floating on the surface 20 of the silicon melt 19 to the centre of the surface 20, where the seed crystal 14 contacts the melt 19. After contact is achieved between the seed crystal 14 and the melt 19, the temperature is adjusted to slightly lower than that of the silicon melting point, 1420° C. Thus, the seed crystal 14 grows larger and is slowly lifted by the rotation and lift device 16, constantly holding contact to the surface 20 of the silicon melt 19. By this, the contaminants floating on the surface 20 of the silicon melt 19 solidify and form one piece with the seed crystal 14, a plug 21. Once the contaminants have solidified into the plug 21, the plug 21 is lifted by the rotation and lift device 16 and popped up from the melt 19. Thus, some of the contaminants are physically removed from the surface 20 of the melt 19. The plug 21 can be removed from the process chamber 4 via the pull chamber 10. For the removal of the plug 21, the process chamber 4 is separated, in particular sealed from the pull chamber 10 by at least one of the isolation door 12 and the isolation valve 11. If needed, more than one plug 21 may be grown to completely remove the contaminants floating on the surface 20 of the melt 19.

After the contaminants have been sufficiently segregated and preferably removed from the melt 19, standard silicon crystal growth procedures are used to grow a high purity silicon crystal. These procedures include seed dipping, seeding and growing a crown 22, shoulder 23, body 24 and tail 25 of a silicon crystal. During crystallization of the melt 19 some of the contaminants which are still dissolved in the melt 19 will segregate due to a segregation coefficient smaller than one.

The contaminants gathered and bonded to the silica sand at the bottom of the crucible 2 are left in the crucible 2 as potscrap 26.

It was found that silicon crystals grown by the above method are pure enough to be used as raw material for solar applications.

What is claimed is:

1. A process for removal of contaminants from a melt of non-ferrous metals comprising the following steps:
providing an apparatus (1) for melting and solidifying non-ferrous metals comprising
a crucible (2) for holding a non-ferrous metal melt and
a process chamber (4), in which the crucible (2) can be placed,
wherein the crucible (2) contains an additive (17),
providing a melt (19) in the crucible (2),
heating the melt (19) in the crucible (2) to a predetermined temperature, whereby the additive (17) can react with contaminants in the melt (19), and
segregating the reacted contaminants from the melt (19).

2. A process according to claim 1, wherein the additive (17) contains silica (SiO₂) sand.

3. A process according to claim 1, wherein the crucible (2) has a coating made of the same material as the additive (17).

4. A process according to claim 1, wherein the additive (17) contains less than 1 ppm-wt impurities.

5. A process according to claim 1, wherein the additive (17) has a particle size distribution with a maximum in the range between 50 μm and 500 μm, in particular between 100 μm and 300 μm.

6. A process according to claim 1, wherein the contaminants are segregated from the melt (19) by at least one of the following processes:
chemical reaction with the additive to form a gas,
physical reaction with the additive to from aggregates,
physical removal from the surface (20) of the melt (19),
segregation in the melt (19) during crystallization of the melt (19) due to a segregation coefficient smaller than 1.

7. A process according to claim 1, wherein the crucible (2) is placed inside the process chamber (4), which is evacuated thereafter.

8. A process according to claim 1, wherein the crucible (2) is placed inside the process chamber (4), to which an inert process gas is introduced.

9. A process according to claim 8, wherein the melt (19) is kept at a temperature, at which the additive reacts with the contaminants to form a gas, which is removed from the process chamber (4).

10. A process according to claim 9, wherein the additive (17) reacts with the contaminants to form carbon mono oxide.

11. A process according to claim 9, wherein the melt is kept at a temperature T>1500° C. for at least 1 h, in particular for a period between 3 h and 5 h.

12. A process according to claim 1, wherein the additive (17) acts as a binder fusing non-dissolvable contaminants to from larger lumps.

13. A process according to claim 1, wherein excess additive (17) disappears from the melt (19) by reacting with it to form a gas.

14. An apparatus (1) for growing high purity silicon crystals comprising
a crucible (2) for melting and solidifying silicon,
a process chamber (4), into which the crucible (2) can be placed,
a temperature controller (5) for controlling the temperature inside the process chamber (4),
wherein the crucible (2) contains an additive (17) of silica sand.
